(19) United States
(12) Patent Application Publication
(10) Pub. No.: US 2021/0313138 A1
(43) Pub. Date: Oct. 7, 2021

(54) MIRROR ELECTRONIC INSPECTION DEVICE

(71) Applicant: Hitachi High-Tech Corporation, Tokyo (JP)

(72) Inventors: Masahiro YAMAOKA, Tokyo (JP); Masaki HASEGAWA, Tokyo (JP); Masakazu SUGAYA, Tokyo (JP); Akihiro FURUKAWA, Tokyo (JP); Katsunori ONUKI, Tokyo (JP)

(73) Assignee: Hitachi High-Tech Corporation, Tokyo (JP)

(21) Appl. No.: 17/266,395

(22) PCT Filed: Sep. 12, 2018
(86) PCT No.: PCT/JP2018/033745

§ 371 Date: Feb. 5, 2021

(51) Int. Cl. H01J 37/20; H01J 37/29

(52) U.S. Cl. CPC H01J 37/20; H01J 37/29

(57) ABSTRACT

Provided is a mirror electronic inspection device which is a defect inspection device for detecting a defect of a semiconductor substrate or the like, and evaluates temperature dependence of the defect in a vacuum. A heating stage including a heater (heat generating element) covered with an electrically insulated insulating material, a heater base on which a sample is mounted, and a heat shielding plate and equipotential surface is mounted on a moving stage installed in a sample chamber of a device via an electrically insulated and thermally insulated fixing member. A heater power supply is connected to the heater (heat generating element), and a sample application power supply is connected to the heater base. The heater power supply and the sample application power supply are electrically separated.

### TECHNICAL FIELD

The present invention relates to a defect inspection device, and more particularly, to a mirror electronic inspection device that inspects a defect based upon an image formed by electron beam emission.

### BACKGROUND ART

In a process of manufacturing a semiconductor device, a fine circuit is formed on a semiconductor wafer polished in a mirror surface shape. When a foreign substance and a scratch, or a crystal defect and an altered layer of a crystal are present on the aforementioned wafer, a defect and material deterioration occur in a process of forming a circuit pattern, a manufactured device does not normally operate or operation reliability thereof deteriorates, such that the manufactured device cannot be used as a product.

SiC used in a power device is superior in various characteristics as a power device material, such as a high dielectric breakdown withstand voltage, chemical stability, and high hardness as compared with a Si semiconductor used in a related art. On the other hand, a crystal defect such as dislocation generated during crystal growth, which directly affects performance of the power device, remains, it is difficult to perform processing and polishing for forming a wafer surface not including crystal disturbance, and it is difficult to completely remove a crystalline alteration layer by processing.

Therefore, in order to secure reliability, it is required to manage the above-described defects existing on the wafer, and a device for detecting the crystal defect with non-destruction and high accuracy is required. Proposed is a mirror electron microscope as one of the methods for realizing non-destructive inspection of the crystal defect and processing damage of such a SiC wafer (refer to JP-A-2016-139685 (PTL 1)).

### CITATION LIST

### Patent Literature

PTL 1: JP-A-2016-139685

### SUMMARY OF INVENTION

### Technical Problem

As described above, the SiC power device is a device that does not require cooling and that can be used at a high temperature, but processing damage and an internal defect exist in a process of manufacturing the SiC power device which is a base material thereof, and there is a possibility of causing internal destruction when the SiC power device is used as a device at the high temperature. However, since a defect extending from a mirror-processed wafer surface to the inside is below an atomic level, it is difficult to grasp the defect even though a surface inspection device using a general optical method of a semiconductor wafer is used.

By performing observation with the mirror electron microscope as disclosed in JP-A-2016-139685 (PTL 1), the internal defect can be noticeably observed with high accuracy, but since the mirror electron microscope does not include a mechanism for heating a sample, temperature dependence of the internal defect cannot be found. Therefore, there is a problem that the mechanism of defect generation, which is difficult to be observed in a normal temperature environment, cannot be detected nondestructively and efficiently.

An object of the present invention is to solve the above-described problems and to provide a mirror electronic inspection device capable of efficiently observing temperature dependence of an internal defect in the state of a base material.

### Solution to Problem

In order to achieve the object thereof, the present invention provides a mirror electronic inspection device, including: a moving stage that moves a sample; an electrically insulated heating stage that is mounted on the moving stage via a fixing member and includes a heater that heats the sample; a sample application power supply that applies a voltage for reflecting an emitted electron before the emitted electron from an electron source hits the sample; and a heater power supply that applies a voltage to the heater.

### Advantageous Effects of Invention

According to the present invention, a heating temperature can be adjusted by a heating stage in a state where a negative voltage is applied to a sample, and it is possible to find out presence or absence of a defect existing inside the sample, a growth process of the defect, and temperature dependence of the defect.

### BRIEF DESCRIPTION OF DRAWINGS

FIG. 1 is a diagram illustrating an outline of a heating stage in the present invention.

FIG. 2 is a diagram illustrating the outline of the heating stage in the present invention.

FIG. 3 is a diagram illustrating the outline of the heating stage in the present invention.

FIG. 4 is a diagram illustrating the outline of the heating stage in the present invention.

FIG. 5 is a diagram illustrating a configuration concept in which the heating stage of the present invention is used in a mirror electron microscope.

FIG. 6A is a diagram illustrating a heat generating element shape of the heating stage in the present invention.

FIG. 6B is a diagram illustrating the heat generating element shape of the heating stage in the present invention.

FIG. 6C is a diagram illustrating the heat generating element shape of the heating stage in the present invention.

FIG. 6D is a diagram illustrating the heat generating element shape of the heating stage in the present invention.

### DESCRIPTION OF EMBODIMENTS

Hereinafter, embodiments for performing the present invention will be described with reference to the drawings. The inventor of the present application considers that temperature dependence of a defect existing inside a sample can be observed by allowing a configuration of a mirror electron microscope to observe a SiC substrate which is the sample and is heated at a predetermined temperature in a vacuum. However, when the observation is performed with the mirror electron microscope, it is necessary to apply a negative voltage which is almost equal to an acceleration voltage of an electron beam to the sample. When the sample to which this negative high voltage is applied or a sample holder on which the sample is mounted is heated with heat conduction, it is necessary to interpose a member having high electrical insulation between a heating heater for the heat conduction and a member to be heated. When the member having the high electrical insulation is not interposed therebetween, a high voltage is applied to a heater power supply and a main body of a device through a conductor of the heating heater, which may cause damage in the device. Hereinafter, various embodiments of a mirror electronic inspection device including an electrically insulated heating stage of the present invention based upon the above-described consideration will be sequentially described.

### First Embodiment

A first embodiment is an embodiment of a mirror electronic inspection device having a configuration in which an electrically insulated heating stage is mounted on a moving stage via a fixing member. That is, the first embodiment is an embodiment of a mirror electronic inspection device including: a moving stage that moves a sample; an electrically insulated heating stage that is mounted on the moving stage via a fixing member and includes a heater that heats the sample; a sample application power supply that applies a voltage for reflecting an emitted electron before the emitted electron from an electron source hits the sample; and a heater power supply that applies a voltage to the heater.

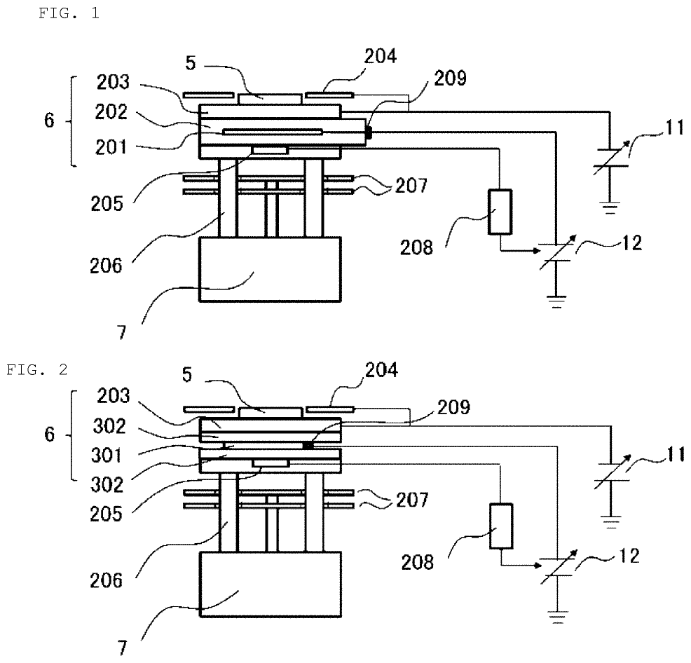

As illustrated in FIG. 1, in the embodiment, a heating stage 6 is mounted on a moving stage 7 to be installed in a sample chamber kept in a vacuum of a mirror electron microscope which will be described later via an electrically insulated and thermally insulated fixing member 206. The fixing member 206 uses a member such as ceramic that secures a sufficient creepage distance against a high voltage applied to the heating stage 6 and that has electrical insulation that does not cause a ground fault to the moving stage 7. It is desirable to use machinable ceramic having low thermal conductivity and high electrical insulation which can be used in a vacuum.

The heating stage 6 includes: a heater (heat generating element) 201 and; an insulating material 202 that surrounds the heater (heat generating element) 201 and electrically insulates the heater (heat generating element) 201; a heater base 203 that is installed above the heater (heat generating element) 201 and is heated by heat conduction and radiation of the heater (heat generating element) 201; a member 204 serving as a heat shielding plate and having an equipotential surface; and a temperature sensor 205.

At least one heat shielding plate 207 is provided between the heating stage 6 and the moving stage 7 in order to cut off radiant heat caused by the heat generation of the heater (heat generating element) 201, whereby an influence of the radiant heat from the heater (heat generating element) 201 on the moving stage 7 can be reduced.

A sample 5 is mounted on the heater base 203 that is heated by the heat conduction and the radiation of the heater (heat generating element) 201 insulated by the insulating material 202. The sample 5 may be mounted on the heater base 203 in a state of being mounted on the sample holder. A thickness of the insulating material 202 is secured so that the heater base 203 to which a high voltage is applied by a sample application power supply 11 and the heater (heat generating element) 201 to which a heater power supply 12 is connected do not cause electrical dielectric breakdown, and a creepage distance from an end of the heater base 203 to a power supply terminal 209 of the heater (heat generating element) 201 is secured, whereby an output of the sample application power supply 11 is configured not to wrap around the heater power supply 12.

The insulating material 202 desirably uses pyrolytic boron nitride (PBN), silicon nitride, aluminum nitride, sapphire, zirconia, yttria, and alumina which have low degassing from the inside of the base material, good thermal conductivity, and high dielectric breakdown strength in the vacuum in the sample chamber. The embodiment uses a heater characterized in a structure in which a heat generating element represented as a pyrolytic graphite (PG)/PBN heater and a ceramic heater is covered with an insulating material except a power supply terminal portion.

The sample 5, the heater base 203, and the member 204 serving as the heat shielding plate and having the equipotential surface have a structure in which a negative voltage is applied thereto from the sample application power supply 11 placed outside the sample chamber of the mirror electron microscope. The heater (heat generating element) 201 has a structure in which electric power is supplied thereto from the heater power supply 12 placed on the outside of the sample chamber of the mirror electron microscope.

In the configuration of this embodiment, heating temperature setting of the sample 5 is performed by controlling the heater power supply 12 by using the temperature sensor 205 and a temperature controller 208 to which an output thereof is connected. At this time, the sample 5, the heater base 205, the member 204, the heater (heat generating element) 201, the temperature sensor 205, and the temperature controller 208 are electrically insulated by the insulating material 202 and electrically separated.

In order to reduce a thermal influence of the radiant heat of the heater (heat generating element) 201 on an objective lens of the mirror electron microscope, and to obtain uniformity of the equipotential surface near the sample, which is a feature of the mirror electron microscope, as illustrated in FIG. 1, the member 204 is arranged to surround the sample on the same plane as the sample surface for the purpose of preventing disturbance on the equipotential surface in the vicinity of the sample. The member 204 formed of a conductive member is arranged and the same potential as the negative voltage applied to the sample 5 is simultaneously applied thereto, thereby making it possible to obtain an observation image having little disturbance on the equipotential surface. The member 204 serving as the heat shielding plate reduces the thermal influence of the radiant heat of the heating stage 6 on the objective lens of the mirror electron microscope. That is, the heating stage 6 includes the member 204 serving as the heat shielding plate and forming the equipotential surface around the sample 5, this member has a disk shape surrounding the sample, and a voltage applied to the sample is applied thereto.

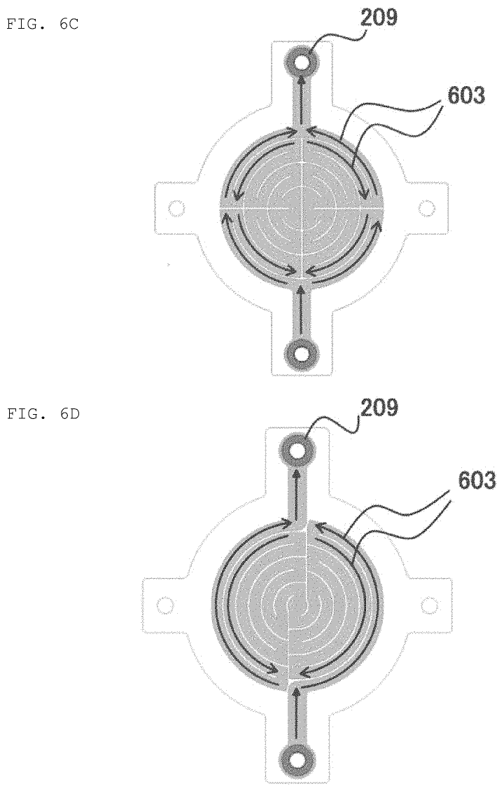

Continuously, a desirable configuration example of a heater (heat generating element) 6 used in the embodiment will be described with reference to FIGS. 6A to 6D. As illustrated in FIG. 6A, the heater (heat generating element) 601 illustrated in gray in the drawing uses a non-magnetic material as a material thereof in order to reduce an influence of a magnetic field 604 on the electron beam, and sets directions of currents 603 flowing through the adjacent heat generating elements to be opposite to each other as illustrated in the drawing. That is, the heater (heat generating element) 601 is a heat generating element including the non-magnetic material, and has a shape that reduces the magnetic field generated from the heat generating element. That is, as a shape for reducing the magnetic field, the heater 601 has a shape including a parallel pattern in which a heating current of the heater power supply 12 flows in an opposite direction. Since the shape of the heat generating element makes it possible to reduce the influence of the magnetic field 604 to be generated by offsetting the direction of the magnetic field 604 generated by the current 603, and the heater (heat generating element) 601 can be maintained in a current carrying state, observation in the mirror electron microscope can be performed in a state of maintaining a temperature set by the temperature controller 208.

FIGS. 6B to 6D illustrate other configuration examples of the shape of the heater (heat generating element) 601. Since the power supply terminal 209 of the heater (heat generating element) illustrated in gray is arranged in a portion away from a main body of the heater (heat generating element), the power supply terminal 209 thereof can reduce the temperature rise of the power supply terminal unit and secure the creepage distance from the end of the mounted heater base 203, thereby making it possible to prevent the high voltage applied to the heater base 203 from being short-circuited to the power supply terminal unit. In FIG. 6B, as compared with the configurations of FIGS. 6C and 6D, two heaters (heat generating elements) illustrated in gray are symmetrically arranged on the left and right sides, such that the directions of the currents 603 flowing through the adjacent heat generating elements can be set to be opposite to each other even in a portion where the creepage distance to the power supply terminal 209 is secured, thereby making it possible to reduce the influence of the generated magnetic field.

According to the embodiment, in the mirror electron microscope, while applying the negative voltage that reflects an emitted electron before the emitted electron hits the sample, the electrically insulated heating stage capable of adjusting the heating temperature of the sample is mounted, thereby making it possible to observe appearance of a defect existing inside the sample, a growth process of the defect, and temperature dependence of the defect, which cannot be observed in a normal temperature environment.

### Second Embodiment

A second embodiment is an embodiment of another configuration in which an electrically insulated heating stage of a mirror electron microscope is mounted on a moving stage via a fixing member. In the following description, a part different from the configuration of the first embodiment will be mainly described, and the description of the same part will be omitted.

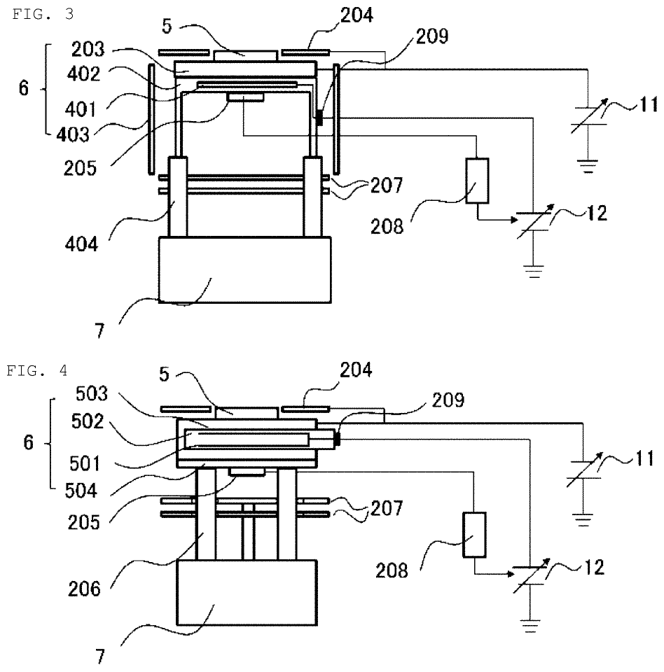

As illustrated in FIG. 2, the heating stage 6 is mounted on the moving stage 7 via the electrically insulated and thermally insulated fixing member 206. In the heating stage 6 of this embodiment, the sample 5 is mounted on the heater base 203 that is heated by heat conduction and radiation of a heater (heat generating element) 301 insulated by electrical insulating materials 302 sandwiching the heater 301 from above and from below. Thicknesses of the upper and lower electrical insulating materials 302 are secured so that the heater base 203 to which a high voltage is applied and the heater (heat generating element) 301 do not cause electrical dielectric breakdown, and a creepage distance from an end of the heater base 203 to the power supply terminal 209 of the heater (heat generating element) 301 is secured, whereby the output of the sample application power supply 11 does not wrap around the heater power supply 12. FIGS. 6A to 6D can be used for a configuration of the heater (heat generating element) 301 in the same manner as that of the first embodiment.

The embodiment is characterized in that the heater (heat generating element) 301 is interposed between the plate-shaped insulating materials 302 respectively arranged above the heater 301 and therebelow. Electric power is supplied to the heater (heat generating element) 301 from the outside by the heater power supply 12. Heating temperature setting of the sample is performed by controlling the heater power supply 12 by using the temperature sensor 205 and the temperature controller 208 via the electrical insulating material 302. At this time, the sample 5, the heater base 203, the member 204, the heater (heat generating material) 301, the temperature sensor 205, and the temperature controller 208 are electrically insulated and electrically separated.

Also in the mirror electron microscope of the embodiment, the member 204 formed of a conductive member is arranged and the same potential as the negative voltage applied to the sample 5 is simultaneously applied thereto, thereby making it possible to obtain a mirror electron observation image having little disturbance on the equipotential surface, and to find out presence or absence of a defect existing inside the sample, a growth process of the defect, and temperature dependence of the defect.

### Third Embodiment

A third embodiment is an embodiment of another configuration in which an electrically insulated heating stage of a mirror electron microscope is mounted on a moving stage via a fixing member. In the following description, a part different from the configuration of the first and second embodiments will be mainly described, and the description of the same part will be omitted.

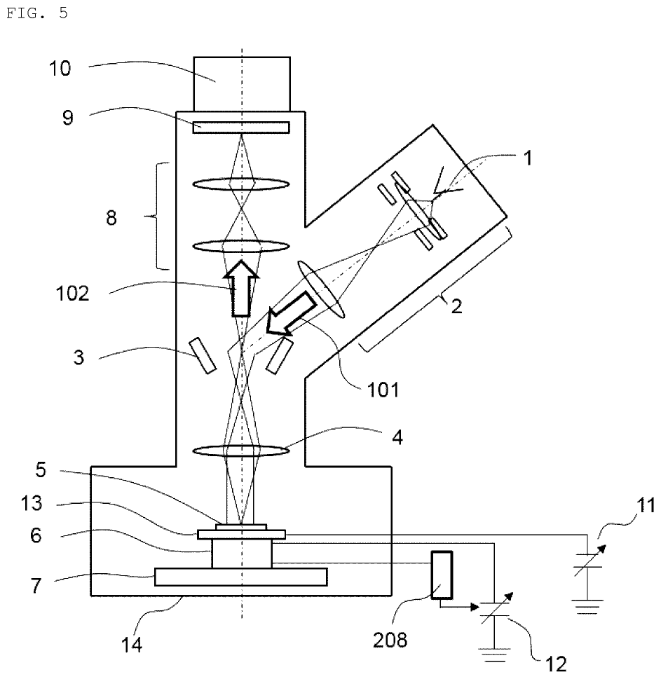

As illustrated in FIG. 3, the heating stage 6 is mounted on the moving stage 7 via an electrically insulated and thermally insulated fixing member 404. The fixing member 404 uses a member such as ceramic that secures a sufficient creepage distance against a high voltage applied to the heating stage 6 and that has electrical insulation that does not cause a ground fault to the moving stage 7. The heating stage 6 mounted on the fixing member 404 includes a cup-shaped insulating material 402. A height of the fixing member 404 is lower than that of the fixing member 206 by an amount corresponding to a height of the cup-shaped insulating material 402. That is, the insulating material 402 has a cup-like shape mounted on the fixing member, and further, the power supply terminal 209 of the heater connected to the heater power supply 12 is arranged on a side surface of the cup-like shaped insulating material.

At least a plurality of heat shielding plates 403 and 207 are provided between the heating stage 6 and the moving stage 7 in order to cut off radiant heat caused by heat generation of a heater (heat generating element) 401, whereby an influence of the radiant heat on the moving stage 7 can be reduced.

The sample 5 is mounted on the heater base 203 heated by heat conduction and radiation of the heater (heat generating element) 401 insulated with the insulating material 402. A thickness of an upper surface of the cup-shaped insulating material 402 is secured so that the heater base 203 to which a high voltage is applied and the heater (heat generating element) 401 do not cause electrical dielectric breakdown, and the height of the side surface of the cup-shaped insulating material 402 is sufficiently secured, whereby a creepage distance up to the power supply terminal of the heater (heat generating element) 401 is secured so that the output of the sample application power supply 11 applied to the heater base 203 does not wrap around the heater power supply 12. FIGS. 6A to 6D can be used for a configuration of the heater (heat generating element) 401 of the embodiment in the same manner as that of the first embodiment.

The embodiment is characterized in a structure in which the heater (heat generating element) 401 is covered with the cup-shaped insulating material 402 except a portion of the power supply terminal 209. In this manner, the heater (heat generating element) 401 covered with the cup-shaped insulating material 402 is used to increase the height of the side surface thereof, whereby as illustrated in FIG. 3, the power supply terminal 209 can be kept away from an end of the heater base 203 and thus the creepage distance is easily secured.

Also in the mirror electron microscope of the embodiment, the member 204 formed of a conductive member is arranged and the same potential as the negative voltage applied to the sample 5 is simultaneously applied thereto, thereby making it possible to obtain a mirror electron observation image having little disturbance on the equipotential surface, and to find out presence or absence of a defect existing inside the sample, a growth process of the defect, and temperature dependence of the defect.

### Fourth Embodiment

A fourth embodiment is an embodiment of another configuration in which an electrically insulated heating stage of a mirror electron microscope is mounted on a moving stage via a fixing member. In the following description, a part different from the configurations of the above-described embodiments will be mainly described, and the description of the same part will be omitted.

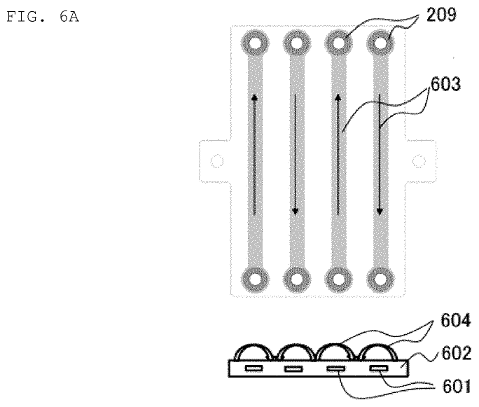

As illustrated in FIG. 4, the heating stage 6 is mounted on the moving stage 7 via the electrically insulated and thermally insulated fixing member 206. The sample 5 is mounted on a heater base 503 heated by heat conduction and radiation of a cylindrical heater (heat generating element) 501 insulated with an electrical insulating material 502. A thickness of the electrical insulating material 502 is secured so that the heater base 503 to which a high voltage is applied and the heater (heat generating element) 501 do not cause electrical dielectric breakdown, and a creepage distance from an end of the heater base 503 to the power supply terminal of the heater (heat generating element) 501 is secured, whereby the output of the sample application power supply 11 does not wrap around the heater power supply 12.

The embodiment uses a cylindrical heater characterized in a structure in which the heat generating element 501 represented as a PG/PBN heater and a ceramic heater is covered with the electrical insulating material 502 except the power supply terminal 209. A plurality of cylindrical heaters may be installed.

Also in the mirror electron microscope of the embodiment, the member 204 formed of a conductive member is arranged and the same potential as the negative voltage applied to the sample 5 is simultaneously applied thereto, thereby making it possible to obtain a mirror electron observation image having little disturbance on the equipotential surface, and to find out presence or absence of a defect existing inside the sample, a growth process of the defect, and temperature dependence of the defect.

### Fifth Embodiment

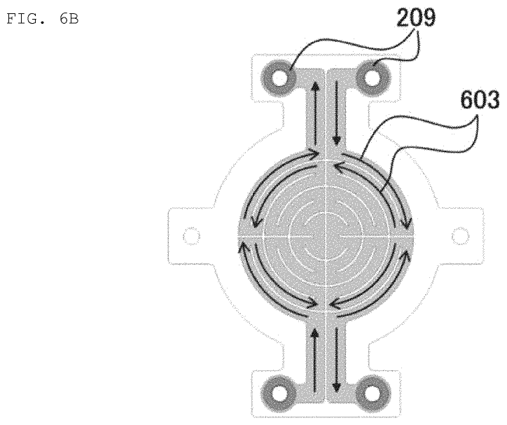

A fifth embodiment is an embodiment of a mirror electron microscope using the heating stage having the configuration described in the first to fourth embodiments. FIG. 5 illustrates a configuration example of the mirror electron microscope using the heating stage described in the first to fourth embodiments. However, in FIG. 5, for example, a vacuum exhaust pump, a control device thereof, a stage control device, an exhaust system piping, and a sample transfer system are omitted.

In the drawing, the mirror electron microscope is configured with two electron optical systems including an emission system 2 that guides an electron beam toward a sample surface as an electron optical mirror body, and an imaging system 8 that forms an image of the electron beam returned from the sample surface, and electronic lenses are respectively provided therein. A separator 3 for separating outgoing and returning electron beams is arranged at a confluent portion of the two electron optical systems. Here, the separator 3 using an E×B deflector that combines an electric field and a magnetic field is used. The E×B deflector can be set to deflect an electron beam coming from above and to straighten an electron beam coming from below.

A sample holder 13 is installed on the moving stage 7 installed in a vacuum-exhausted sample chamber 14 via an electrical insulating member, and the sample 5 is mounted on the sample holder 13. As described above, the sample 5 may be placed directly on the heating stage 6 without using the sample holder 13. As a drive system of the moving stage 7, two orthogonal linear motions, and in addition thereto, a linear motion in a vertical direction and a motion in a tilting direction may be added. The above-described motions allow the moving stage 7 to move the whole surface of the sample 5 or a part of the surface thereof to a position on an optical axis of the objective lens 4, which is an electron beam emission position.

In order to form a negative potential on the sample surface, the sample application power supply 11 which is a high voltage power supply applies a negative voltage which is almost equal to the acceleration voltage of the electron beam to the sample holder 13. As described in the first to fourth embodiments, the sample application power supply 11, the heater power supply 12, and the temperature controller 208 are installed outside the sample chamber.

An emission electron beam 101 is decelerated in front of the sample by a deceleration electric field formed by the negative voltage applied to the sample holder 13. The negative voltage applied to the sample holder 13 is adjusted so that an electron orbit is reversed in an opposite direction before colliding with the sample 5. An electron reflected by the sample 5 becomes a mirror electron 102, passes through the electron optical system 8 of the imaging system, and is photographed by a camera 10 via a fluorescent plate 9. Description of a photographed image is omitted here.

Since the mirror electron microscope of the embodiment has a configuration using the electrically insulated heating stage including, for example, the heater (heat generating element) and the member serving as the heat shielding plate and having the equipotential surface described in the first to fourth embodiment, heating temperature adjustment can be performed in a state where the negative voltage is applied to the sample, and it is possible to find out presence or absence of a defect existing inside the sample, a growth process of the defect, and temperature dependence of the defect, which cannot be observed under a room temperature.

The present invention is not limited to the above-described embodiments, and includes various modifications. For example, the embodiments are described in detail for better understanding of the present invention, and are not necessarily limited to the one including all the configurations of the description. While the above-described embodiments are described by using the mirror electronic inspection device such as the mirror electron microscope, the embodiments can also be applied to a charged particle beam device such as an electron microscope.

### REFERENCE SIGNS LIST

1: electron source
2: condenser lens
3: separator
4: objective lens
5: sample
6: heating stage
7: moving stage
8: electron lens
9: fluorescent plate
10: camera
11: sample application power supply
12: heater power supply
13: sample holder
14: sample chamber
101: outgoing electron
102: returning electron
201, 301, 401, 501, 601: heater (heat generating element)
202, 302, 402, 502, 504, 602: insulating material
203, 503: heater base
204: member
205: temperature sensor
206, 404: fixing member
207, 403: heat shielding plate
208: temperature controller
209: power supply terminal
603: current direction
604: magnetic field to be generated by current

1. A mirror electronic inspection device, comprising:
a moving stage that moves a sample;
an electrically insulated heating stage that is mounted on the moving stage via a fixing member and includes a heater that heats the sample;
a sample application power supply that applies a voltage for reflecting an emitted electron before the emitted electron from an electron source hits the sample; and
a heater power supply that applies a voltage to the heater.

2. The mirror electronic inspection device according to claim 1,
wherein the heating stage includes an insulating material that electrically insulates the sample application power supply and the heater power supply.

3. The mirror electronic inspection device according to claim 2,
wherein the insulating material is arranged to surround the heater.

4. The mirror electronic inspection device according to claim 1,
wherein the heating stage includes a member serving as a heat shielding plate and forming an equipotential surface around the sample.

5. The mirror electronic inspection device according to claim 4,
wherein the member has a disk shape surrounding the sample, and a voltage applied to the sample is applied thereto.

6. The mirror electronic inspection device according to claim 1,
wherein the heater is a heat generating element formed of a non-magnetic material, and has a shape that reduces a magnetic field generated from the heat generating element.

7. The mirror electronic inspection device according to claim 6,
wherein the shape that reduces the magnetic field includes a parallel pattern in which a heating current of the heater power supply flows in an opposite direction.

8. The mirror electronic inspection device according to claim 2,
wherein the insulating material has a cup-like shape mounted on the fixing member.

9. The mirror electronic inspection device according to claim 8,
wherein a power supply terminal of the heater connected to the heater power supply is arranged on a side surface of the insulating material having the cup-like shape.

10. The mirror electronic inspection device according to claim 2,
wherein the fixing member includes at least one heat shielding plate that cuts off radiant heat from the heating stage.
